(19) United States
(12) Patent Application Publication
(10) Pub. No.: US 2002/0024109 A1
(43) Pub. Date: Feb. 28, 2002

(54) Integrated circuit and method for magnetic sensor testing

(76) Inventor: Kambiz Hayat-Dawoodi, Plano, TX (US)

Correspondence Address: TEXAS INSTRUMENTS INCORPORATED, P O BOX 655474, M/S 3999, DALLAS, TX, 75265

(21) Appl. No.: 09/941,005

(22) Filed: Aug. 27, 2001

Related U.S. Application Data
(60) Provisional application No. 60/228,062, filed on Aug. 29, 2000.

(51) Int. Cl. H01L 43/00; H01L 29/82

(52) U.S. Cl. 257/421

(57) ABSTRACT

An integrated circuit includes a magnetic sensor that comprises a region of conductive material operable to receive a current from a current source and to conduct the current through the region of conductive material. At least one conductive node is electrically connected to the region of conductive material and is operable to allow measurement of a differential voltage arising due to a magnetic field acting on the region of conductive material. A copper conductor is disposed adjacent the region of conductive material such that a current through the copper conductor generates a magnetic field.

### BACKGROUND OF THE INVENTION

Magnetic sensors are elements that sense magnetic fields. There are numerous applications for magnetic sensors. For example, one such application is for current measurement, such as power management for personal computers. In addition, magnetic sensors can also be used for position sensing, such as to measure angles, distances, or rotations. For example, magnetic sensors could be used in automotive applications for position sensing of throttles, pedals, or valves. Important characteristics for magnetic sensors are accuracy, low-cost production, and good linearity.

Testing costs of magnetic sensors is one of the main reasons behind their relative expense; it is a challenge to manufacturers of magnetic sensors to test them in an efficient and economical manner. Since a large enough magnetic field needs to be generated to test the accuracy and linearity of the magnetic sensors over their entire linear region, most manufacturers use complex non-standard test headers and complex equipment to test magnetic sensors. Furthermore, depending on the application intended for the magnetic sensor, it may be desired to produce various magnetic field patterns to test the magnetic sensors. This increases the need for complex test equipment, thereby further increasing testing cost.

The problem of expensive magnetic sensor testing was previously addressed by surrounding magnetic sensors on an integrated circuit with a current-carrying conductor on the integrated circuit. This current-carrying conductor was made of aluminum, which resulted in the disadvantage of not being able to conduct enough current to generate a large enough magnetic field to test the linearity of the magnetic sensor. The aluminum current-carrying conductor on the integrated circuit produced enough magnetic field to let the designers know that it was working, i.e. that the magnetic sensor was sensing something, but it could not produce enough magnetic field to test the magnetic sensor's linearity.

### SUMMARY OF THE INVENTION

The challenges in the field of integrated circuits continue to increase with demands for more and better techniques having greater flexibility and adaptability. Therefore, a need has arisen for a new integrated circuit and method for magnetic sensor testing.

In accordance with the present invention, an integrated circuit and method for magnetic sensor testing is provided that addresses disadvantages and problems associated with previously developed systems and methods.

According to one embodiment of the invention, an integrated circuit includes a magnetic sensor that comprises a region of conductive material operable to receive a current from a current source and to conduct the current through the region of conductive material. At least one conductive node is electrically connected to the region of conductive material and is operable to allow measurement of a differential voltage arising due to a magnetic field acting on the region of conductive material. A copper conductor is disposed adjacent the region of conductive material such that a current through the copper conductor generates a magnetic field.

According to another embodiment of the invention, a method for magnetic sensor testing includes providing a magnetic sensor having a region of conductive material that is operable to receive a current from a current source and to conduct the current through the region of conductive material, and electrically connecting at least one conductive node to the region of conductive material. The at least one conductive node is operable to allow measurement of a differential voltage arising due to a magnetic field acting on the region of conductive material. The method also includes generally surrounding the region of conductive region with a copper conductor, and generating a current through the copper conductor thereby generating the magnetic field. The method further includes measuring the differential voltage across the region of conductive material to determine a sensed magnetic field, and comparing the sensed magnetic field to the magnetic field generated by the copper conductor.

Embodiments of the invention provide numerous technical advantages. For example, a technical advantage of one embodiment of the present invention is that a significant reduction in the cost of production testing of magnetic sensors is realized by producing integrated circuits having current-carrying conductors adjacent the magnetic sensors. These conductors can generate the required magnetic fields needed to test the magnetic sensors, thus eliminating the need for external test headers or complex testing equipment thereby reducing cost. Another technical advantage of one embodiment of the present invention is that a myriad of magnetic field patterns can be generated to simulate what the magnetic sensor will encounter in actual use. This significantly reduces the production costs of magnetic sensors by eliminating the need for external test headers or complex testing equipment.

Other technical advantages are readily apparent to one skilled in the art from the following figures, descriptions, and claims.

### BRIEF DESCRIPTION OF THE DRAWINGS

For a more complete understanding of the invention, and for further features and advantages, reference is now made to the following description, taken in conjunction with the accompanying drawings, in which:

FIG. 1A is a schematic diagram illustrating one embodiment of an integrated circuit in accordance with the present invention;

FIG. 1B is a block diagram of the integrated circuit of FIG. 1A;

FIG. 2 is a plan view of one type of a magnetic sensor adjacent a current-carrying conductor of the integrated circuit of FIG. 1A in accordance with one embodiment of the present invention;

FIGS. 3A through 3D are cross-sectional views of a portion of the integrated circuit of FIG. 1A, illustrating various construction stages of a magnetic sensor adjacent a current-carrying conductor in accordance with one embodiment of the present invention; and

FIG. 4 is a flowchart demonstrating one method of testing a magnetic sensor in accordance with the present invention.

### DETAILED DESCRIPTION OF EMBODIMENTS OF THE INVENTION

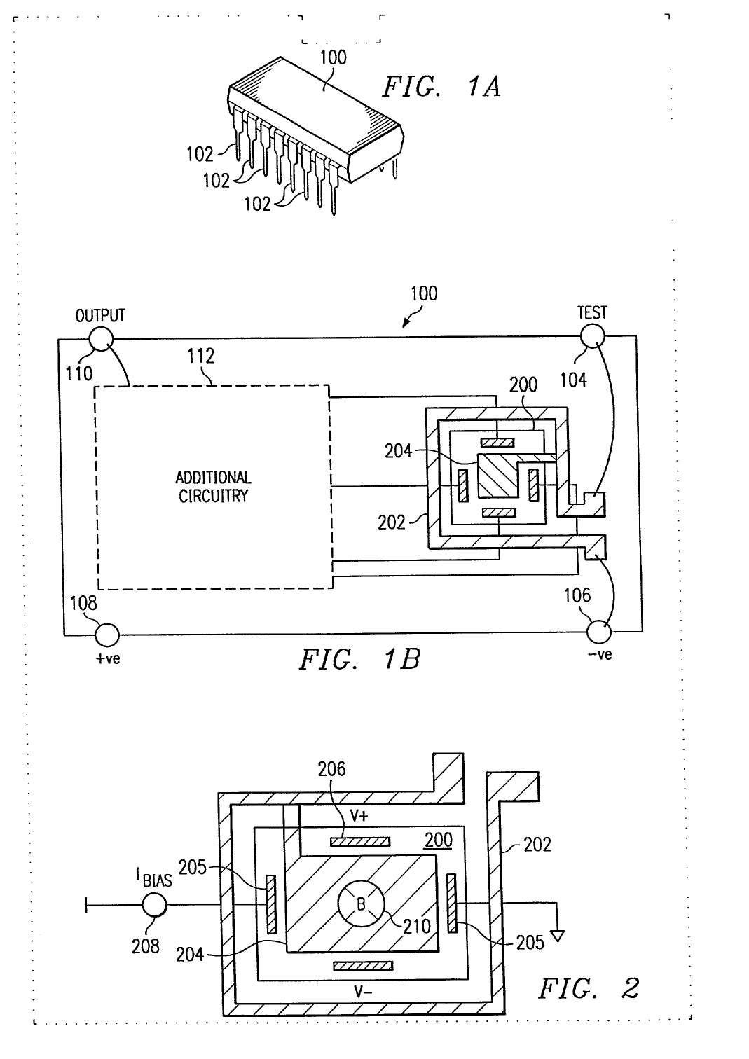

Embodiments of the present invention and their advantages are best understood by referring now to FIG. 1A through 4 of the drawings, in which like numerals refer to like parts.

FIG. 1A is a schematic diagram illustrating one embodiment of an integrated circuit 100 in accordance with the present invention. Integrated circuit 100 is shown to be a dual in-line package; however, any type of integrated circuit can be used, such as a quad flat package. Integrated circuit 100 is shown in FIG. 1A to have sixteen pins 102; however, any number of pins 102 can be used such as four or eight. Integrated circuits are used for numerous applications in electronics, one example being magnetic sensing. Magnetic sensors are used for a number of applications, some of which are position sensing in automotive applications, or other electrical applications such as current sensing. One consideration in production of magnetic sensors is how best to test them in an efficient and cost-effective way. The present invention solves this by eliminating the need for external test headers or complex testing equipment by producing integrated circuit 100 with an internal conductor 202 surrounding a magnetic sensor 200, as shown in FIG. 1B. This significantly reduces cost.

FIG. 1B is a block diagram illustrating integrated circuit 100 of FIG. 1A. Integrated circuit 100 includes magnetic sensor 200, conductor 202, an electric shield plate 204, additional circuitry 112, a test pin 104, a negative supply pin 106, a positive supply pin 108, and an output pin 110. Only four pins are shown in FIG. 1B for clarity. Other pins may be present, and these pins can be used for many different applications. As described above, the testing problem associated with magnetic sensors is solved by the present invention by disposing conductor 202 adjacent magnetic sensor 200 directly on-chip. In one embodiment, conductor 202 is used to test magnetic sensor 200 by utilizing the Hall effect.

According to the Hall effect, if a magnetic field is applied perpendicular to a conductive region that carries a current, an electric field is produced transverse to that current, thus establishing a potential difference commonly referred to as the Hall voltage. If the current magnitude is known, then the Hall voltage can be measured to determine the magnitude of the magnetic field.

In the illustrated embodiment, a current is sent through magnetic sensor 200 and a magnetic field 210 is applied perpendicular to magnetic sensor 200 by sending another current through conductor 202, as shown in FIG. 2, which diverts the carriers created by the current sent through magnetic sensor 200. The Hall voltage across magnetic sensor 200, which is transverse to the current flow, is measured using additional circuitry 112 and output pin 110. Then the magnitude of the sensed magnetic field, given by output pin 110, can be compared to magnetic field 210 that was generated by sending a current through conductor 202.

The linearity of magnetic sensor 200 over its entire linear region can also be tested. For example, a small current can be sent through conductor 202 to see if magnetic sensor 200 is working for small magnetic fields, and then a large current can be sent through conductor 202 to see if magnetic sensor 200 is working for larger magnetic fields. In this way, the linearity of magnetic sensor 200 can be tested, which is important for accurate and reliable magnetic sensors. A technical advantage of the present invention is that magnetic fields greater than 100 gauss can be produced near the center region of magnetic sensor 200, as shown best in FIG. 2. This helps in testing the linearity of magnetic sensor 200. In addition to different magnetic field magnitudes, the present invention allows different magnetic field patterns to be produced depending on the intended application for magnetic sensor 200. Furthermore, any number of magnetic sensors 200 can be produced on integrated circuit 100, and they can be arranged in any pattern or orientation.

FIG. 2 is a plan view of one type of magnetic sensor 200 adjacent conductor 202 in accordance with one embodiment of the present invention. FIG. 2 shows magnetic sensor 200 adjacent to, and generally surrounded by, conductor 202. Conductive nodes 205 electrically couple magnetic sensor 200 to current source 208, and conductive nodes 206 electrically couple magnetic sensor 200 to additional circuitry 112 (as seen best in FIG. 1B). Electric shield plate 204 is also shown in FIG. 2 to be generally shielding magnetic sensor 200, while being electrically coupled to conductor 202.

In one embodiment, magnetic sensor 200 is a Hall element; however, other types of magnetic sensors can be utilized. A Hall element is a sensing element that takes advantage of the Hall effect by providing a current through a region of conductive material 302 using conductive nodes 205 to provide a differential voltage indicative of an electric field transverse to region of conductive material 302. This differential voltage is measured using conductive nodes 206 and senses magnetic field 210 that is applied perpendicular to magnetic sensor 200. Magnetic sensor 200 can have any shape desired depending on its intended application. For example, as shown in FIG. 2, magnetic sensor 200 can be generally square or it can be in the shape of a cross, a rectangle, a circle, or other shapes. The size of magnetic sensor 200 can also vary. In the embodiment shown in FIG. 2, magnetic sensor 200 is generally square with a surface area no greater than approximately one thousand square micrometers (1000 μm²). As an example, magnetic sensor 200 can have a width of 30 micrometers and a length of 30 micrometers for a total of nine hundred square micrometers. A technical advantage of the present invention is to produce magnetic sensors in small sizes so that on-chip conductors can produce high ranges of magnetic fields thereby allowing the cost-effective testing of both the accuracy and linearity of magnetic sensors.

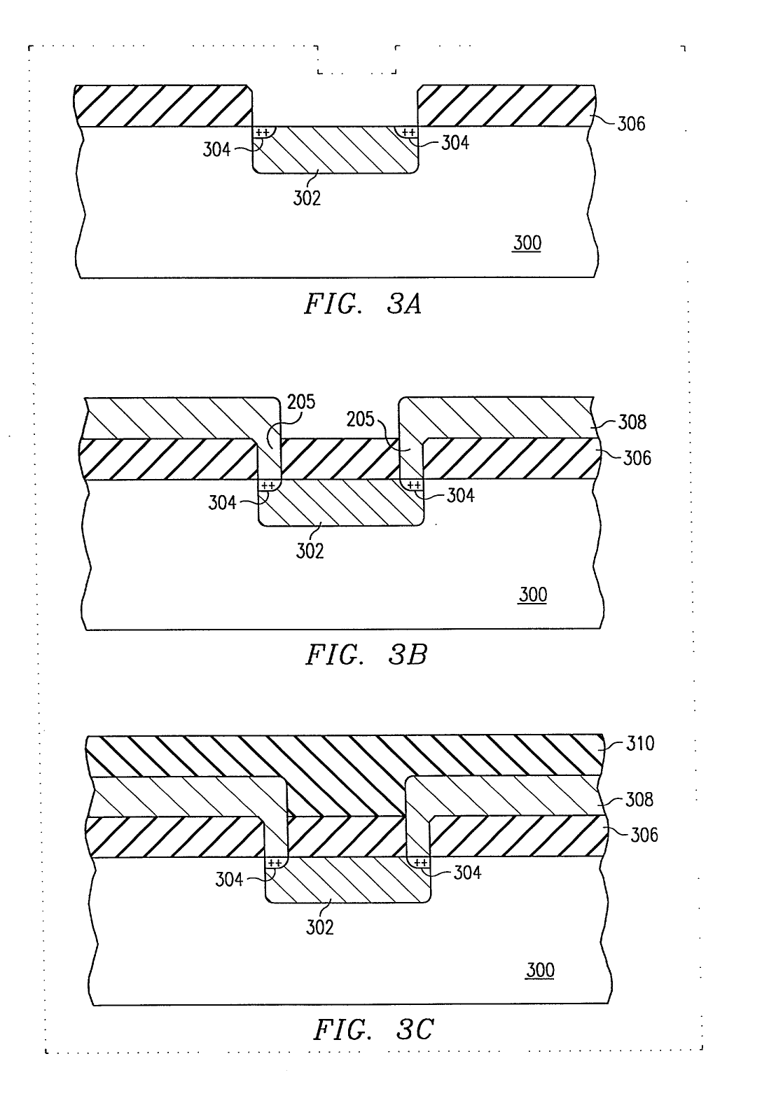

Magnetic sensor 200 includes region of conductive material 302 that allows current to flow thereby creating carriers to be diverted. Region of conductive material 302 can be an n-well (shown best in FIG. 3A), or can be other conductive regions such as a metal plate. Current that flows through region of conductive material 302 comes from current source 208 shown in FIG. 2.

Current source 208 generates a biased current thereby creating carrier movement through region of conductive material 302 using conductive nodes 205. These carriers are needed because once magnetic field 210 is applied perpendicular to magnetic sensor 200 the carriers are diverted in a direction transverse to the current and, consequently, a differential voltage across magnetic sensor 200 can be measured using conductive nodes 206 and additional circuitry 112. Current source 208 can be generated on-chip as shown best in FIG. 1B, or can be generated externally.

Conductive nodes 205, 206 are conductive regions electrically connected to region of conductive material 302 and are used to, for example, conduct a current through region of conductive material 302 and to measure the differential voltage produced when magnetic field 210 is applied perpendicular to magnetic sensor 200. FIG. 2 shows two conductive nodes 205 and two conductive nodes 206; however, magnetic sensor 200 may have any number of conductive nodes depending on the requirements for magnetic sensor 200. Conductive nodes 205, 206 may be coupled to additional circuitry 112 so that, for example, an output can be generated for measurement of the magnetic field sensed. However, one or more conductive nodes 205, 206 may not be coupled to additional circuitry 112 such as, for example, when current source 208 is produced externally.

As mentioned previously, magnetic field 210 is generated by running a current through conductor 202 to test magnetic sensor 200. Magnetic field 210 is denoted as B as shown in FIG. 2, and can be a positive or a negative magnetic field depending on the configuration of conductor 202 and the direction of the current flowing through conductor 202. Magnetic field 210 can have many different magnitudes and can have many different types of patterns depending on how much current is sent through conductor 202 or depending on the configuration of conductor 202. When testing magnetic sensor 200 one of the main areas of concern is near the center region of magnetic sensor 200. Therefore, the designer/engineer of integrated circuit 100 can pattern conductor 202 in a manner that produces a desired magnetic field near the center region of magnetic sensor 200.

Still referring to FIG. 2, conductor 202 is formed from copper. Copper is an excellent conductor; therefore, a high current density can be achieved. This means that there can be a large current going through conductor 202 while the cross-sectional area of conductor 202 remains somewhat small. By utilizing this high current density with small magnetic sensors, large enough magnetic field magnitudes can be generated on-chip to test the linearity of magnetic sensors. This is one advantage of using copper for conductor 202. The ability to generate the required magnetic field magnitudes eliminates the need for external test headers or complex testing equipment thereby reducing cost. In one embodiment, conductor 202 has a generally square configuration as shown in FIG. 2. However, conductor 202 may have many different types of shapes and patterns as discussed previously. In one embodiment, one end of conductor 202 is coupled to test pin 104 (see FIG. 1B), and the other end of conductor 202 is connected to negative supply pin 106. In this embodiment, test pin 104 and negative supply pin 106 are used to generate the desired current. However, any method can be used to generate a current through conductor 202.

Conductor 202 may also have electric shield plate 204 coupled thereto. In one embodiment, electric shield plate 204 is a metal plate; however, electric shield plate 204 may just be a region of conductive material. Electric shield plate 204 may be coupled to conductor 202 or may be coupled to some other potential. Any method of producing an electric field in electric shield plate 204 can be used. Electric shield plate 204 shields magnetic sensor 200 from any outside electric fields or high frequency signals, while allowing magnetic fields to pass through. Electric shield plates are sometimes required because magnetic sensors can sometimes be influenced by outside electric fields or high frequency signals, thus reducing the ability to test magnetic sensors in an accurate manner.

Referring back to FIG. 1B, additional circuitry 112 is shown to comprise a portion of integrated circuit 100. Additional circuitry 112 may be any type of electric circuitry such as, for example, amplification, modulation, or demodulation. In one embodiment, additional circuitry 112 provides current source 208 and receives a signal from magnetic sensor 200 that characterizes a differential voltage when magnetic field 210 is applied to magnetic sensor 200. Additional circuitry 112 then modifies the signal's generated output for measurement in testing magnetic sensor 200.

FIGS. 3A-3D are cross-sectional views of a portion of integrated circuit 100, illustrating various construction stages of a magnetic sensor adjacent to a current-carrying conductor in accordance with one embodiment of the present invention. FIGS. 3A-3D show only one embodiment of the construction of integrated circuit 100 in accordance with the present invention.

FIG. 3A shows a semiconductor substrate 300, region of conductive material 302 disposed outwardly from substrate 300, n+ regions 304 adjacent region of conductive material 302, and first isolation dielectric layer 308 disposed outwardly from substrate 300. In one embodiment, substrate 300 is a P-type silicon; however, substrate 300 may be formed from other suitable materials used in wafer fabrication of semiconductors. As discussed above, in one embodiment, region of conductive material 302 is an n-well; however, region of conductive material 302 may be other types of conductive regions such as a metal plate. Region of conductive material 302 has adjacent n+ regions 304 for producing better electrical connections with conductive nodes 205, 206. n⁺ regions 304 can be created using an implantation process or other doping processes. First dielectric layer 308, which is disposed outwardly from substrate 300, may comprise, for example, one or more dielectric materials such as oxide, nitride, oxynitride or a heterostructure comprising alternate layers of oxide and nitride.

FIG. 3B shows the addition of a metal layer 308 disposed outwardly from first dielectric layer 306. FIG. 3B also shows conductive nodes 205 (conductive nodes 206 are not shown for clarity) vertically disposed downwardly from metal layer 308 electrically coupling to n⁺ regions 304. Metal layer 308 may be any type of conductive material such as copper, aluminum or titanium. Metal layer 308 is grown or deposited using any conventional fabrication methods used in semiconductor processing.

FIG. 3C illustrates a second isolation dielectric layer 310 disposed outwardly from metal layer 308. There is also a portion of second isolation dielectric layer 310 that is disposed outwardly from first dielectric layer 306. As described above with first dielectric layer, second dielectric layer 310 may be one or more dielectric materials such as oxide, nitride, oxynitride, or a heterostructure comprising alternate layers of oxide and nitride, and may be grown or deposited using any conventional fabrication methods used in semiconductor processing.

FIG. 3D illustrates a cross section of a portion of integrated circuit 100 showing conductor 202 and electric shield plate 204 disposed outwardly from second isolation dielectric layer 310. Electric shield plate 204, as discussed above, may or may not be disposed outwardly from second dielectric layer 310 depending on the particular application for magnetic sensor 200. Electric shield plate 204 also may or may not be coupled to conductor 202 as described above. The cross-section shown in FIG. 3D is only one portion of integrated circuitn 100 used for testing magnetic sensors.

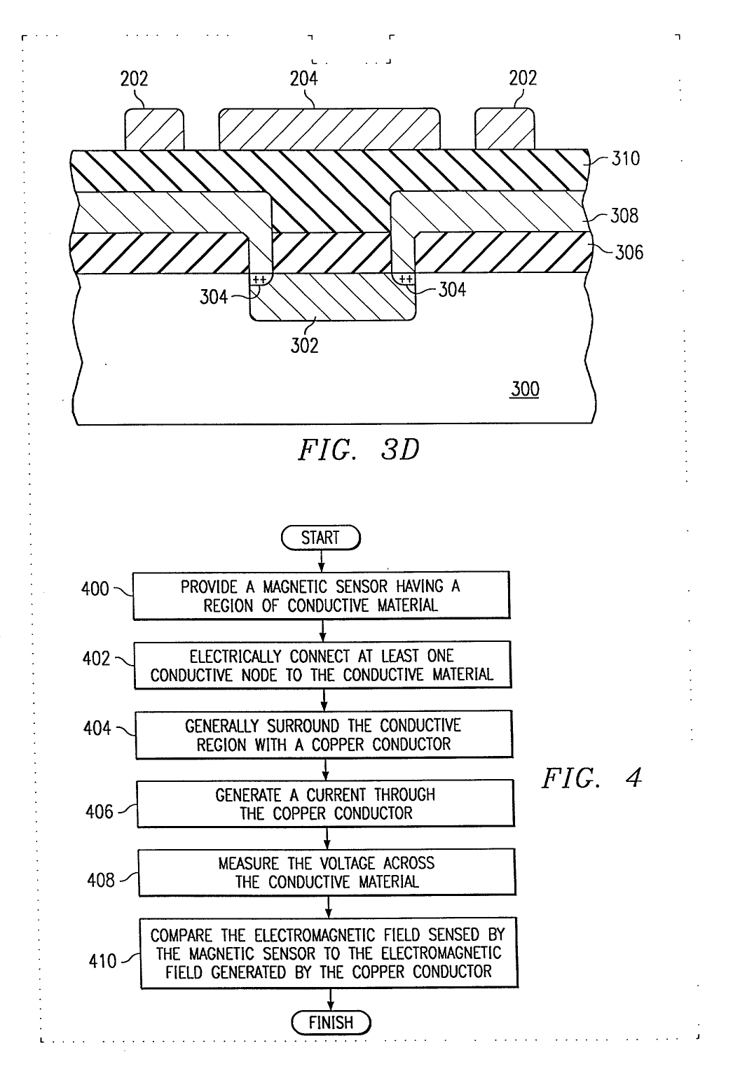

FIG. 4 illustrates a method of testing magnetic sensors in accordance with one embodiment of the present invention. Magnetic sensor 200 having region of conductive material 302 is provided, as indicated by box 400. At least one conductive node 205, 206 is electrically connected to region of conductive material 302, as indicated by box 402. Region of conductive material 302 is disposed adjacent copper conductor 202, as shown by box 404. A current is generated through copper conductor 202, as indicated by box 406. This current generates a magnetic field 210, which diverts the carriers flowing through region of conductive material 302 thereby creating a differential voltage across magnetic sensor 202 that is transverse to the current flowing. This differential voltage is then measured (see box 408), and compared to the magnetic field that was generated by copper conductor 202, as indicated by box 410. This comparison is used to determine whether magnetic sensor 200 is working properly. Different magnitudes of current and, hence, magnetic fields, can be generated to test the linearity of magnetic sensor 200 over the entire linear region of magnetic sensor 200.

Although embodiments of the invention and their advantages are described in detail, a person skilled in the art could make various alternations, additions, and omissions without departing from the spirit and scope of the present invention as defined by the appended claims.

What is claimed is:

1. An integrated circuit, comprising:
a magnetic sensor, the magnetic sensor comprising:
a region of conductive material operable to receive a current from a current source and operable to conduct the current through the region of conductive material; and
at least one conductive node electrically connected to the region of conductive material and operable to allow measurement of a differential voltage arising due to a magnetic field acting on the region of conductive material; and
a copper conductor disposed adjacent the region of conductive material such that a current through the copper conductor generates the magnetic field.

2. The integrated circuit of claim 1 wherein the magnetic sensor is a Hall element.

3. The integrated circuit of claim 1 wherein the region of conductive material comprises an n-well formed in a semiconductor substrate.

4. The integrated circuit of claim 1 wherein the conductive node is electrically connected to a corresponding external connector on the integrated circuit.

5. The integrated circuit of claim 4 wherein the external connector is a pin.

6. The integrated circuit of claim 1 further comprising an electric shield plate generally shielding the region of conductive material.

7. The integrated circuit of claim 1 wherein the copper conductor is operable to produce a magnetic field induction of at least 100 Gauss.

8. The integrated circuit of claim 1 wherein the magnetic sensor has a surface area less than approximately 1000 μm².

9. A method for testing a magnetic sensor comprising:
providing a magnetic sensor having a region of conductive material operable to receive a current from a current source and operable to conduct the current through the region of conductive material;
electrically connecting at least one conductive node to the region of conductive material, the at least one conductive node operable to allow measurement of a differential voltage arising due to a magnetic field acting on the region of conductive material;
generally surrounding the region of conductive region with a copper conductor;
generating a current through the copper conductor thereby generating the magnetic field;
measuring the differential voltage across the region of conductive material to determine a sensed magnetic field; and
comparing the sensed magnetic field to the magnetic field generated by the copper conductor.

10. The method of claim 9 wherein the magnetic sensor is a Hall element.

11. The method of claim 9 wherein providing a region of conductive material comprises forming an n-well in a semiconductor substrate.

12. The method of claim 9 further comprising electrically connecting the conductive node to a corresponding external connector on the integrated circuit.

13. The method of claim 12 wherein the external connector is a pin.

14. The method of claim 9 further comprising generally shielding the region of conductive material with an electric shield plate.

15. The method of claim 9 further comprising producing a magnetic field induction of at least 100 Gauss in the copper conductor.

16. The method of claim 9 further comprising manufacturing the magnetic sensor with a surface area less than approximately 1000 μm².

17. A method of forming an integrated circuit for magnetic sensor testing, comprising:
forming a region of conductive material in a semiconductor substrate, the region of conductive material having input and output conductive nodes;
forming a first isolation dielectric layer on the semiconductor substrate;
forming a metal layer on the first isolation dielectric layer;
coupling the metal layer to the input and output conductive nodes of the region of conductive material;
forming a second isolation dielectric layer on the metal layer; and
forming a copper conductor on the second isolation dielectric layer.

18. The method of claim 17 wherein the region of conductive material is an n-well.

19. The method of claim 17 further comprising electrically connecting the input and output conductive nodes to a corresponding external connector on the integrated circuit.

20. The method of claim 19 wherein the external connector is a pin.

21. The method of claim 17 further comprising forming an electric shield plate on the second isolation dielectric layer.
